(19) United States
(12) Patent Application Publication
(10) Pub. No.: US 2007/0246809 A1
(43) Pub. Date: Oct. 25, 2007

(54) Package for optical device and method of manufacturing the same

(75) Inventor: Yoshiki Takayama, Shiga (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/785,178

(22) Filed: Apr. 16, 2007

(30) Foreign Application Priority Data
Apr. 24, 2006 (JP) 2006-118616
Mar. 7, 2007 (JP) 2007-056477

(51) Int. Cl. H01L 23/495

(52) U.S. Cl. 257/676

(57) ABSTRACT

A package for an optical device includes a plurality of ceramic layers 101, 102 and 103 stacked on a base 2 and a recessed portion 18 formed to mount an optical element at the center. Reversely rounded portions 11 are formed on the corners of the ceramic layers 100, 101 and 102 such that at least one of the four corners of the top ceramic layer 103 has an outside shape placed outside the outside shapes of the corners of the ceramic layers 100, 101 and 102 with respect to the center.

### FIELD OF THE INVENTION

The present invention relates to an optical device such as a solid-state imaging device used for a digital still camera, a digital video camera, a camera phone, and so on.

### BACKGROUND OF THE INVENTION

In recent years, in digital still cameras, digital video cameras (movie), camera phones, and so on cost reduction has been demanded more and more in addition to a high pixel density, high picture quality, and miniaturization. Thus it is demanded to further reduce the sizes and costs of optical devices such as a solid-state imaging device mounted in these apparatuses.

Japanese Patent Laid-Open No. 2001-28431 and so on describe a solid-state imaging device as a representative example of an optical device using a ceramic package, as shown in FIGS. 10A and 10B.

FIG. 10A is a plan view of the solid-state imaging device. FIG. 10B is a sectional view taken along line B-BB of FIG. 10A.

A solid-stage imaging element 7 acting as an optical element is fixed on a base 2 with an adhesive 8 in a recessed package 1. The terminals of the solid-stage imaging element 7 are electrically connected, via bonding wires 9, to internal terminals 4 disposed in the package 1. A lid 10 such as a glass plate for keeping airtightness in the package 1 is bonded to the opening of the top surface of the package 1. Reference numeral 5 denotes an external terminal drawn from the internal terminal 4.

In this solid-state imaging device, the packages 1 are divided by breaking. Further, blurs on the four corners during a break may cause a defect of the outside shape and dust, and thus reversely rounded portions 11 are provided on the four corners to prevent the occurrence of blurs, reducing the cost.

However, in this method, a clearance 13 is set from the outside shape of the lid 10 to the outside shape of the package 1 in consideration of the mounting accuracy and component tolerance of the lid 10, and the clearance 13 requires a space for the dimensions and the tolerances of the reversely rounded portions 11, so that the outside shape of the solid-state imaging device is expanded.

FIGS. 11A and 11B show a solid-state imaging device using a conventional ceramic package having a smaller size. FIG. 11A is a plan view of the solid-state imaging device. FIG. 11B is a sectional view taken along line C-CC of FIG. 11A.

In this solid-state imaging device, packages 1 are divided by dicing, so that no blurs occur on the four corners. Thus reversely rounded portions 11 are not necessary and a clearance 13 from the outside shape of a lid 10 to the outside shape of the package 1 has no extra space, thereby achieving miniaturization.

### DISCLOSURE OF THE INVENTION

In the method of dividing the packages 1 by dicing, no blurs occur on the four corners. Thus the reversely rounded portions 11 are not necessary and the solid-state imaging device can be miniaturized. However, the dicing cost is high and increases the cost of the package 1.

Although the cost is reduced in the method of dividing the packages 1 by breaking, the reversed rounded portions 11 for preventing blurs are necessary on the four corners. Thus the outside dimensions of the solid-state imaging device cannot be as small as those in dicing, so that cost reduction and miniaturization mutually contradict each other.

Therefore, a major challenge is to reduce the outside dimensions of an optical device as in dicing while reducing the cost of the package 1 as in breaking.

The present invention is designed to solve the problem and has as its object the provision of a package for an optical device whereby the packages are divided by breaking enabling low cost and simultaneously the outside dimensions of an optical device such as a solid-state imaging device can be reduced as in dicing.

A package for an optical device according to claim 1 of the present invention is a package including at least two stacked plate-like members and a recessed portion formed to mount an optical element at the center, wherein at least one of the four corners of the plate-like member of the top layer has an outside shape placed, with respect to the center, outside the outside shape of the corner of the plate-like member of each layer disposed under the plate-like member of the top layer.

A package for a solid-state imaging device according to claim 2 of the present invention is a package including at least two stacked plate-like members and a recessed portion formed to mount a solid-state imaging element at the center, wherein at least one of the four corners of the plate-like member of the top layer has an outside shape placed, with respect to the center, outside the outside shape of the corner of the plate-like member of each layer disposed under the plate-like member of the top layer.

A package for an optical device according to claim 3 of the present invention is a package including a plurality of ceramic layers stacked on a base and a recessed portion formed to mount an optical element at the center, wherein at least one of the four corners of the top ceramic layer has an outside shape placed, with respect to the center, outside the outside shape of the corner of the ceramic layer disposed under the top ceramic layer.

A package for a solid-state imaging device according to claim 4 of the present invention is a package including a plurality of ceramic layers stacked on a base and a recessed portion formed to mount a solid-state imaging element at the center, wherein at least one of the four corners of the top ceramic layer has an outside shape placed, with respect to the center, outside the outside shape of the corner of the ceramic layer disposed under the top ceramic layer.

A package for an optical device according to claim 5 of the present invention is a package including a recessed portion formed to mount an optical element at the center, the package further including a package bottom having the recessed portion formed at the center and a package top joined onto the package bottom, wherein at least one of the four corners of the package top has an outside shape placed outside the outside shape of the corner of the package bottom with respect to the center.

A package for a solid-state imaging device according to claim 6 of the present invention is a package including a recessed portion formed to mount a solid-state imaging element at the center, the package including a package bottom having the recessed portion formed at the center and a package top joined onto the package bottom, wherein at least one of the four corners of the package top has an outside shape placed outside the outside shape of the corner of the package bottom with respect to the center.

A package for a solid-state imaging device according to claim 7 of the present invention, in claim 4, wherein the top layer is formed of a plurality of ceramic layers.

A package for a solid-state imaging device according to claim 8 of the present invention, in claim 2, wherein at a point where the corner of the plate-like member of the top layer has an outside shape placed outside the outside shape of the corner of the plate-like member disposed under the plate-like member of the top layer, the corner of the plate-like member disposed under the plate-like member of the top layer is formed into a blur preventing shape including a round, a reversely rounded portion, a chamfer, a notch, and a recess.

A package for a solid-state imaging device according to claim 9 of the present invention, in claim 6, wherein at a point where the corner of the package top has an outside shape placed outside the outside shape of the corner of the package bottom with respect to the center, the plate-like member disposed under the plate-like member of the top layer has a corner formed into blur preventing shape including a round, a reversely rounded portion, a chamfer, a notch, and a recessed portion.

A package for a solid-state imaging device according to claim 10 of the present invention, in claim 8, further comprising one of side plating and underside plating, the side plating being formed on a portion having the blur preventing shape, the underside plating being formed to correspond to the portion having the blur preventing shape on the bottom of the package.

A package for a solid-state imaging device according to claim 11 of the present invention, in claim 9, further comprising one of side plating and underside plating, the side plating being formed on a portion having the blur preventing shape, the underside plating being formed to correspond to the portion having the blur preventing shape on the bottom of the package.

A package for a solid-state imaging device according to claim 12 of the present invention, in claim 4, wherein at least one of the four corners of the plate-like member of the bottom layer has an outside shape placed, with respect to the center, outside the outside shapes of the corners of the plate-like members other than the plate-like member of the top layer, out of the plate-like members of the layers disposed on the plate-like member of the bottom layer.

A package for a solid-state imaging device according to claim 13 of the present invention, in claim 12, wherein the bottom layer is formed of a plurality of ceramic layers.

A method of manufacturing a package for an optical device according to claim 14 of the present invention, when dividing a laminated sheet including stacked ceramic sheets into pieces and forming the package for the optical device, the package including a recessed portion formed to mount a solid-state imaging element at the center, the method comprising: forming a first sheet on a ceramic sheet of a base, the first sheet including the stacked ceramic sheets having a first hole formed on a portion corresponding to the recessed portion of each package; forming a second hole on at least one of corners of portions corresponding to the four corners of each package of the first sheet, the second hole acting as a blur preventing shape when the sheet is divided into pieces; stacking a second sheet on the first sheet, the second sheet having a third hole formed to correspond to the first hole; forming a cut on a portion corresponding to the outside shape of each package on at least one of the top surface and the underside of a laminated sheet of the first sheet and the second sheet; baking the laminated sheet including the first sheet and the second sheet with the formed cut; and dividing the laminated sheet at the cut into packages after the baking.

A method of manufacturing a package for a solid-state imaging device according to claim 15 of the present invention, when dividing a laminated sheet including stacked ceramic sheets into pieces and forming the package for the solid-state imaging device, the package including a recessed portion formed to mount a solid-state imaging element at the center, the method comprising: forming a first sheet on a ceramic sheet of a base, the first sheet including the stacked ceramic sheets having a first hole formed on a portion corresponding to the recessed portion of each package; forming a second hole on at least one of corners of portions corresponding to the four corners of each package of the first sheet, the second hole acting as a blur preventing shape when the sheet is divided into pieces; stacking a second sheet on the first sheet, the second sheet having a third hole formed to correspond to the first hole; forming a cut on a portion corresponding to the outside shape of each package on at least one of the top surface and the underside of a laminated sheet of the first sheet and the second sheet; baking the laminated sheet including the first sheet and the second sheet with the formed cut; and dividing the laminated sheet at the cut into packages after the baking.

A solid-state imaging device according to claim 16 of the present invention, comprising a solid-state imaging element on a recessed portion of the package for a solid-state imaging device according to claim 2.

A solid-state imaging device according to claim 17 of the present invention, comprising a solid-state imaging element on a recessed portion of the package for a solid-state imaging device according to claim 4.

A solid-state imaging device according to claim 18 of the present invention, comprising a solid-state imaging element on a recessed portion of the package for a solid-state imaging device according to claim 6.

According to the package for an optical device of the present invention, blurs caused by dividing a sheet into pieces by breaking can be prevented without blur preventing shapes such as reversely rounded portions on the four corners of the top layer. Thus a clearance from the outside shape of the lid of the optical device to the outside shape of the package requires no extra space. As a result, the outside dimensions of the optical device can be as small as those in dicing while the sheet is divided into pieces by breaking enabling low cost.

### BRIEF DESCRIPTION OF THE DRAWINGS

FIG. 1A is a plan view of a solid-state imaging device using a package of (First Embodiment) of the present invention;

FIG. 1B is a sectional view taken along line A-AA of FIG. 1A;

FIG. 2A is a sectional view showing the first half of a method of manufacturing the package of (First Embodiment);

FIG. 2B is a plan view showing the first half of the method of manufacturing the package of (First Embodiment);

FIG. 3A is a sectional view showing the last half of the method of manufacturing the package of (First Embodiment);

FIG. 3B is a sectional view showing the formation of cuts according to (First Embodiment);

FIG. 4A is a plan view showing a solid-state imaging device of (First Embodiment);

FIG. 4B is a plan view showing the solid-state imaging device of (First Embodiment);

FIG. 5 is a plan view showing a solid-state imaging device of another embodiment;

FIG. 6A is a sectional view of a solid-state imaging device using a package of (Second Embodiment) of the present invention;

FIG. 6B is a rear view of (Second Embodiment);

FIG. 6C is a rear view of another example;

FIG. 7A is a sectional view of a solid-state imaging device using a package of (Third Embodiment) of the present invention;

FIG. 7B is a rear view of (Third Embodiment);

FIG. 8A is a sectional view of a solid-state imaging device using a package of (Fourth Embodiment) of the present invention;

FIG. 8B is a rear view of (Fourth Embodiment);

FIG. 9A is a sectional view showing stacking during the resin molding of a package according to (Fifth Embodiment) of the present invention;

FIG. 9B is a sectional view of (Fifth Embodiment);

FIG. 10A is a plan view showing a solid-state imaging device using a conventional package obtained by breaking;

FIG. 10B is a sectional view showing the conventional example;

FIG. 11A is a plan view showing a solid-state imaging device using a conventional package obtained by dicing; and

FIG. 11B is a sectional view showing the conventional example.

### DESCRIPTION OF THE EMBODIMENT(S)

Exemplary embodiments of the present invention will now be described below in accordance with the accompanying drawings.

### First Embodiment

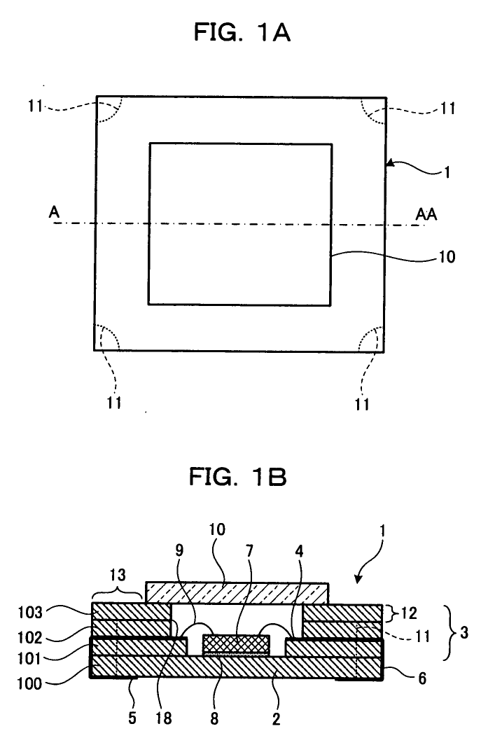

FIGS. 1A and 1B to 5 show (First Embodiment) of the present invention.

FIG. 1A is a plan view of a solid-state imaging device using a package for a solid-state imaging device according to (First Embodiment) of the present invention. FIG. 1B is a sectional view taken along line A-AA of FIG. 1A.

As shown in FIGS. 1A and 1B, a package 1 for a solid-state imaging device (hereinafter, will be simply referred to as the package 1) has a recessed portion 18 formed by a base 2 and a side wall 3 rising on the outer edge of the base 2.

The base 2 includes a plate-like ceramic layer 100, and the side wall 3 includes plate-like ceramic layers 101, 102 and 103. Further, the ceramic layer 101 has a pair of opposed surfaces and the opposed surfaces protrude inward. A plurality of internal terminals 4 are disposed on the top surface of the ceramic layer 101, and external terminals 5 electrically connected to the internal terminals 4 are disposed on the outer surface of the side wall 3.

The solid-state imaging device is configured such that a solid-stage imaging element 7 is fixed on the base 2 in the recessed portion 18 of the package 1 with an adhesive 8, the plurality of terminals of the solid-stage imaging element 7 are respectively connected to the internal terminals 4 via bonding wires 9 and drawn to the external terminals 5, and a lid 10 such as a glass plate is placed on the top surface of the top ceramic layer 103.

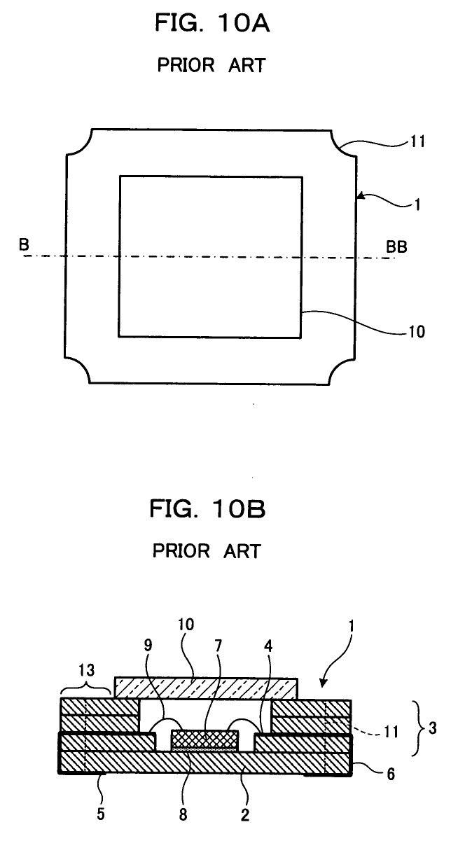

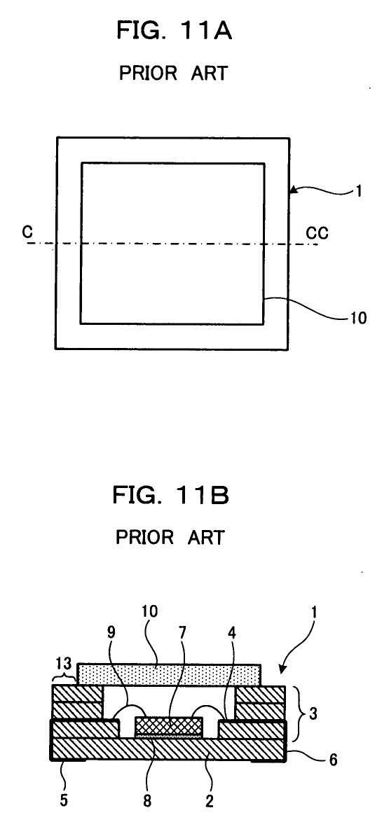

The package 1 is different from the foregoing conventional package illustrated in FIGS. 10A, 10B, 11A and 11B in that reversely rounded portions 11 for preventing blurs are provided on the four corners of the ceramic layers 100, 101 and 102 placed under the ceramic layer 103 but the reversely rounded portions are not formed on the four corners of the top plate-like ceramic layer 103, and in that the outside shapes of the four corners of the uppermost plate-like ceramic layer 103 are placed outside the outside shapes of the four corners of the ceramic layers 100, 101 and 102 placed under the ceramic layer 103.

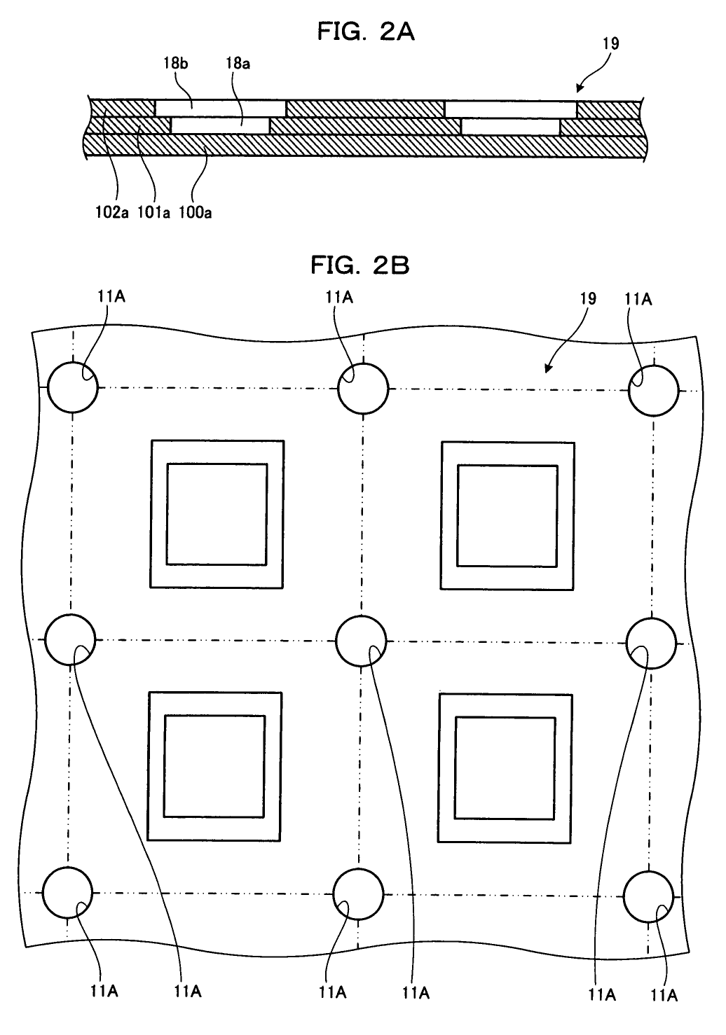

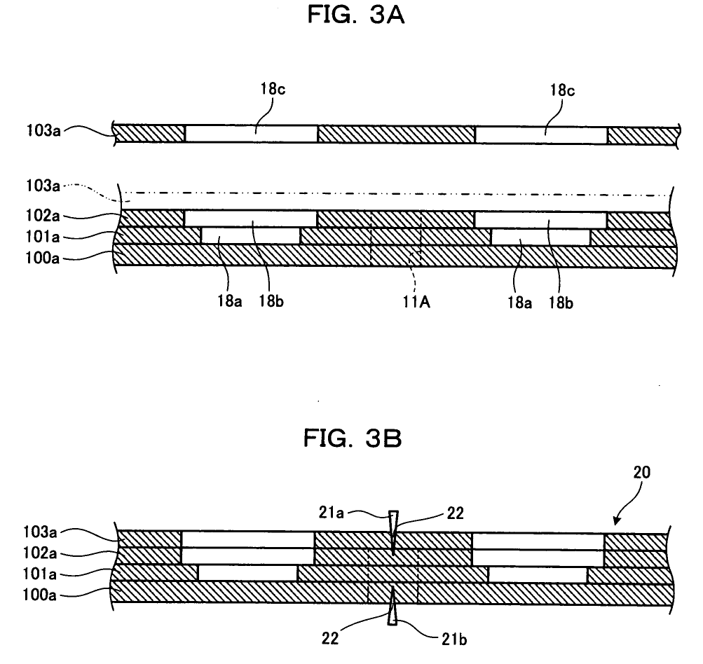

The package 1 used in this solid-state imaging device is manufactured in steps illustrated in FIGS. 2A, 2B, 3A and 3B.

First, as shown in FIG. 2A, ceramic sheets 100a, 101a and 102a serving as the ceramic layers 100, 101 and 102 are stacked to form a first sheet 19. Reference numeral 18a denotes holes formed on the ceramic sheet 101a and reference numeral 18b denotes holes formed on the ceramic sheet 102a.

Next, as shown in FIG. 2B, second holes 11A acting as blur preventing shapes are formed on portions corresponding to the four corners of the packages of the first sheet 19. In FIG. 2B, areas to be formed as packages later are indicated by virtual lines.

And then, as shown in FIG. 3A, a ceramic sheet 103a is stacked as a second sheet on the first sheet 19 including the second holes 11A. On the ceramic layer 103a used as the ceramic layer 103 later, only holes 18C are formed. The holes 18C correspond to the holes 18b formed on the ceramic sheet 102a, and each of the holes 18C forms a part of the recessed portion 18. No holes are formed on positions corresponding to the second holes 11A of the first sheet 19.

Further, as shown in FIG. 3B, on a laminated sheet 20 including the stacked ceramic sheets 100a, 101a, 102a and 103a, cuts 22 are formed by cutters 21a and 21b on a portion corresponding to the outside shape of each package on the top ceramic sheet 103a and the bottom ceramic sheet 10a.

And then, the laminated sheet 20 formed with the cuts 22 is baked. After the baking, the laminated sheet 20 is divided at the cuts 22 into packages.

In this way, only the ceramic layers 100, 101 and 102 are divided into pieces by breaking. To be specific, the reversely rounded portions 11 for preventing blurs are provided on the four corners of the ceramic layers 101 and 102 but are not provided on the four corners of the ceramic layer 103. Therefore, a clearance 13 from the outside shape of the lid 10 of the solid-state imaging device to the outside shape of the package 1 requires no extra space, and the outside dimensions of the solid-state imaging device can be as small as those in dicing while the laminated sheet 20 is divided into pieces by breaking enabling low cost.

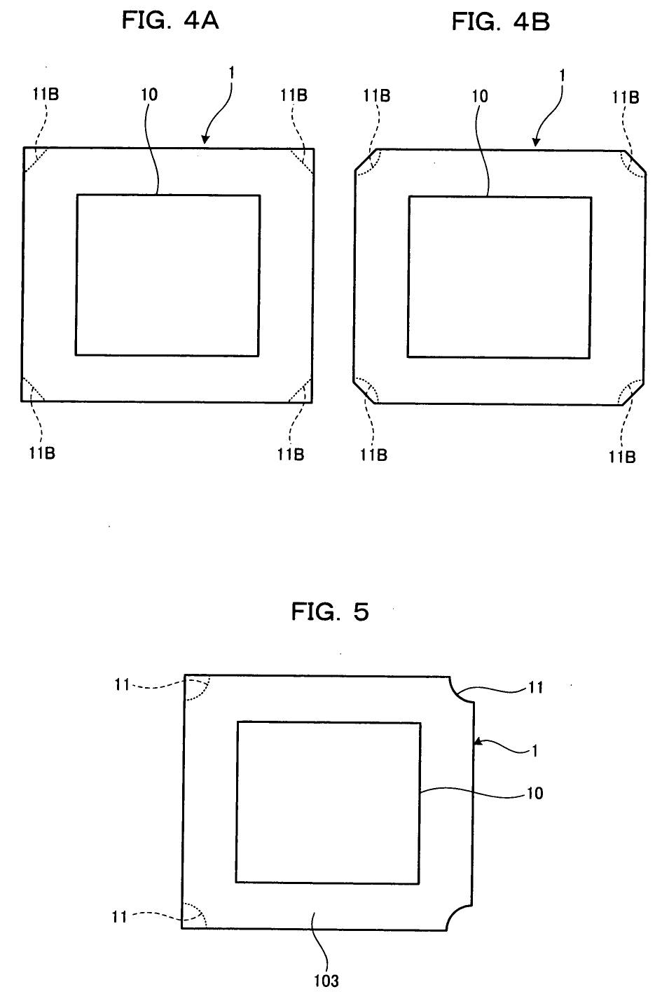

As blur preventing shapes 11B on the four corners of the ceramic layers 100, 101 and 102 placed under the top ceramic layer 103, as shown in FIGS. 4A and 4B, it is possible to set the most suitable shapes including a round, a chamfer, a C plane, a notch, an ellipse, and a recessed portion on the corners according to the configuration. Also on the four corners of the ceramic layer 103, the most suitable shapes can be set according to the configuration.

Although the top ceramic layer 103 is a single layer, the configuration is not limited to the above and the ceramic layer 103 may include a plurality of layers according to the configuration.

The reversely rounded portions 11 are not formed on any one of the four corners of the ceramic layer 103. However, as shown in FIG. 5, the ceramic layer 103 can include corners not having the shapes of the reversely rounded portions 11 for preventing blurs like the lower ceramic layers 100, 101 and 102 and corners having the shapes of the reversely rounded portions 11 for preventing blurs like the lower ceramic layers 100, 101 and 102. The shapes of the corners may be set according to the purpose and the configuration.

In this configuration, the internal terminals 4 and the external terminals 5 are illustrated as the inner leads and the outer leads of a lead section 6. The configuration of the lead section 6 is not limited to the above. Further, the number of ceramic layers is not limited and thus can be set at a proper number according to the configuration and wiring.

In the present embodiment, on the top ceramic sheet 103a and the bottom ceramic sheet 100a, the cuts 22 are formed by the cutters 21a and 21b on a portion corresponding to the outside shape of each package. The cut 22 on a portion corresponding to the outside shape of each package may be formed only on one of the top ceramic sheet 103a and the bottom ceramic sheet 100a to divide the laminated sheet 20 into pieces by breaking.

In the plan view of FIG. 5 showing the solid-state imaging device, at least one of the four corners of the ceramic layer 100 serving as a bottom plate-like member may have an outside shape placed, with respect to the center, outside the outside shapes of the corners of the ceramic layers 101 and 102 other than the ceramic layer 103 on the ceramic layer 100, and the laminated sheet 20 may be divided by breaking.

### Second Embodiment

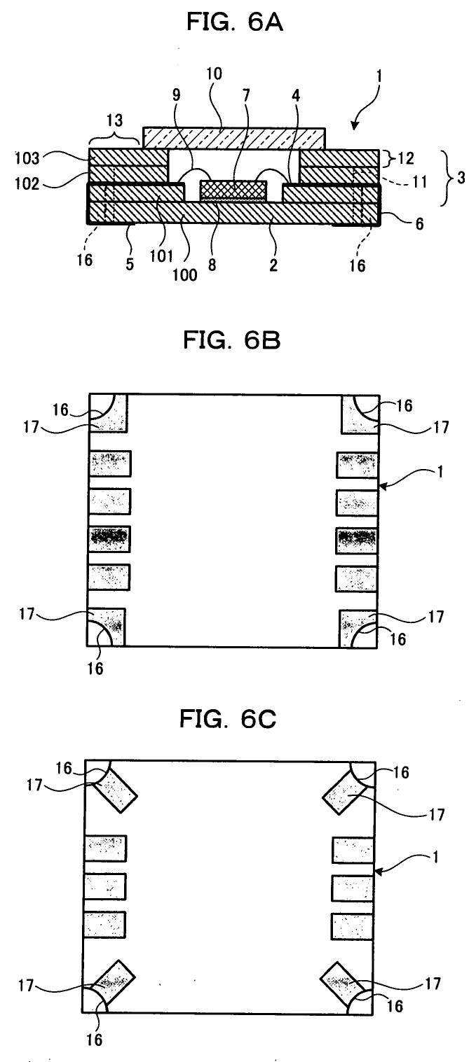

FIGS. 6A and 6B show (Second Embodiment) of the present invention.

FIG. 6A is a side view of a solid-state imaging device using a package of (Second Embodiment) of the present invention. FIG. 6B is a rear view of the solid-state imaging device.

A package 1 is different from that of (First Embodiment) in that side plating 16 is applied on reversely rounded portions 11 for preventing blurs on a ceramic layer 100 below a top ceramic layer 103 and underside plating 17 is applied on the bottom of the ceramic layer 100 so as to correspond to the reversely rounded portions 11 shaped to prevent blurs. Thus the reversely rounded portions 11 can be also used as reinforcing lands for soldering or external terminals for electrical connection.

The underside plating 17 may be formed as shown in FIG. 6C. Although the side plating 16 is applied on the ceramic layer 100, the side plating 16 can be also applied on ceramic layers 101 and 102. The underside plating 17 can be electrically connected to the side plating 16 and also to an internal electric circuit and other connection terminals via through holes formed on the ceramic layer 100 and so on.

The side plating 16 and the underside plating 17 are applied in the present embodiment. Only one of the underside plating 17 and the side plating 16 may be applied in some packaging forms.

### Third Embodiment

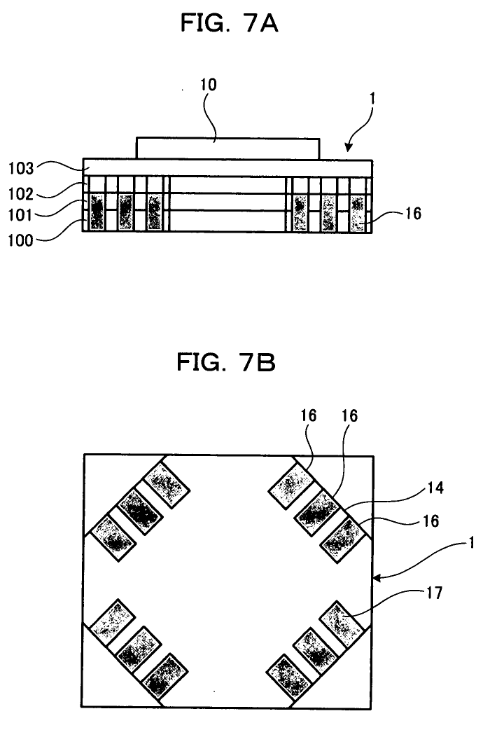

FIGS. 7A and 7B show (Third Embodiment) of the present invention.

FIG. 7A is a side view of a solid-state imaging device using a package of (Third Embodiment) of the present invention. FIG. 7B is a rear view of the solid-state imaging device.

A package 1 of (Third Embodiment) is different from that of (First Embodiment) in that C planes 14 for preventing blurs are expanded on the four corners of ceramic layers 100, 101 and 102 below a top ceramic layer 103 and external terminals made up of side plating 16 and underside plating 17 are disposed on the C planes 14. With this configuration, a soldering area can be reduced and set within the outermost shape of the package 1, thereby miniaturizing a mounting substrate and a set product. Further, the shape of the C plane 14 is not limited to the above and an optimum shape can be used according to the configuration.

### Fourth Embodiment

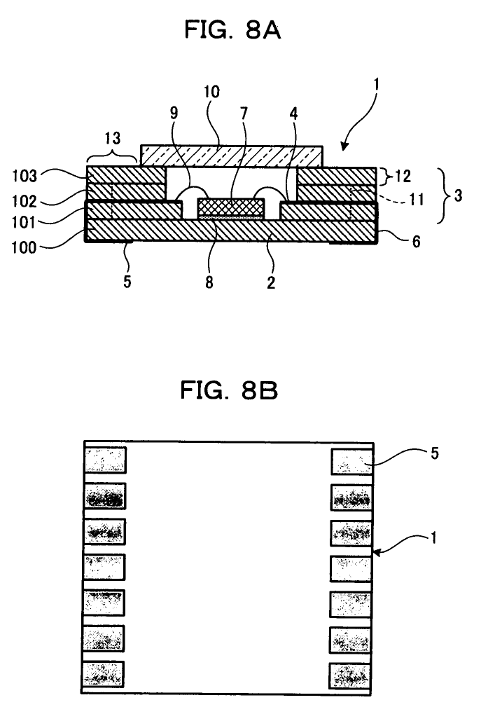

FIGS. 8A and 8B show (Fourth Embodiment) of the present invention.

FIG. 8A is a sectional view of a solid-state imaging device using a package of (Fourth Embodiment) of the present invention. FIG. 8B is a rear view of the package.

The package 1 of (Fourth Embodiment) is different from that of (Third Embodiment) in that the outside shapes of the four corners of a ceramic layer 100 serving as a bottom ceramic layer are placed outside the outside shapes of the four corners of ceramic layers 101 and 102 disposed on the ceramic layer 100 and the ceramic layer 100 is divided into pieces by cutters as the ceramic layer 103, so that reversely rounded portions 11 are not provided on the four corners of the ceramic layer 100.

With this configuration, the spaces of the four corners on the underside can be effectively used, a number of external terminals 5 can be disposed as shown in FIG. 8B, and large reinforcing lands can be disposed on the four corners.

### Fifth Embodiment

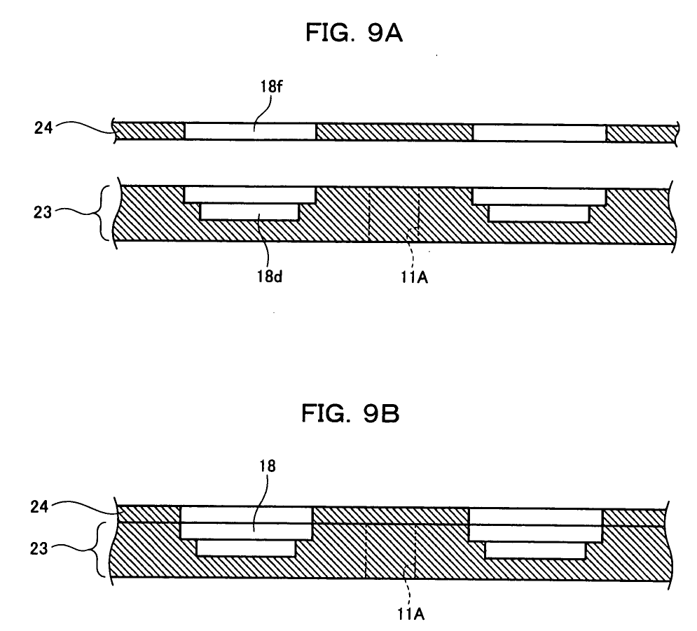

FIGS. 9A and 9B are sectional views showing the steps of manufacturing a package according to (Fifth Embodiment) of the present invention.

In the foregoing embodiments, stacked and baked ceramic sheets were described as an example. In (Fifth Embodiment), a package formed by resin molding will be described as an example.

As in the foregoing embodiments, the package for a solid-state imaging device includes a recessed portion 18 for mounting a solid-state imaging element at the center. As shown in FIG. 9A, a package bottom 23 having a recessed portion 18d formed at the center and a package top 24 bonded on the package bottom 23 are resin-molded.

As in FIG. 2B, the package bottom 23 is resin-molded such that second holes 11A acting as blur preventing shapes are formed on portions corresponding to the four corners of each package.

The package top 24 includes a hole 18f formed to correspond to the recessed portion 18d but includes no holes formed on a position corresponding to the second hole 11A.

As shown in FIG. 9B, the package bottom 23 and the package top 24 are joined to each other by bonding and the like. After cuts 22 are formed as in FIG. 3B, the packages are divided by breaking.

The package of Fifth Embodiment is similar to those of the foregoing embodiments except that the package is made up of the resin-molded package bottom 23 and package top 24. For example, at points where the outside shapes of the corners of the package top 24 are placed outside the outside shapes of the corners of the package bottom 23 with respect to the center, the corners of the package bottom 23 are formed into blur preventing shapes including a round, a reversely rounded portion, a chamfer, a notch, and a recessed portion. Further, side plating is formed on portions having the blur preventing shapes and underside plating is similarly formed on the underside of the package bottom 23.

In the foregoing embodiments, the solid-state imaging device was described as a specific example of an optical device and the packaged solid-state imaging element was described as an optical element. Other optical devices can be also used in a similar manner. Another specific example of a packaged optical device includes a packaged laser-emitting element and a reflective optical device made up of a single package of a laser-emitting element and a light-receiving element.

According to the present invention, packages can be divided by breaking enabling low cost and size reduction can be achieved as dicing. Thus the present invention is useful for manufacturing a digital still camera, a digital video camera, a camera phone, and the like requiring both of low cost and miniaturization.

What is claimed is:

1. A package for an optical device, the package comprising at least two stacked plate-like members and a recessed portion formed to mount an optical element at a center,
wherein at least one of four corners of the plate-like member of a top layer has an outside shape placed, with respect to the center, outside an outside shape of a corner of the plate-like member of each layer disposed under the plate-like member of the top layer.

2. A package for a solid-state imaging device, the package comprising at least two stacked plate-like members and a recessed portion formed to mount a solid-state imaging element at a center,
wherein at least one of four corners of the plate-like member of a top layer has an outside shape placed, with respect to the center, outside an outside shape of a corner of the plate-like member of each layer disposed under the plate-like member of the top layer.

3. A package for an optical device, the package comprising a plurality of ceramic layers stacked on a base and a recessed portion formed to mount an optical element at a center,
wherein at least one of four corners of the top ceramic layer has an outside shape placed, with respect to the center, outside an outside shape of a corner of the ceramic layer disposed under the top ceramic layer.

4. A package for a solid-state imaging device, the package comprising a plurality of ceramic layers stacked on a base and a recessed portion formed to mount a solid-state imaging element at a center,
wherein at least one of four corners of the top ceramic layer has an outside shape placed, with respect to the center, outside an outside shape of a corner of the ceramic layer disposed under the top ceramic layer.

5. A package for an optical device, the package comprising a recessed portion formed to mount an optical element at a center,
the package further comprising a package bottom having the recessed portion formed at the center and a package top joined onto the package bottom, wherein at least one of four corners of the package top has an outside shape placed outside an outside shape of a corner of the package bottom with respect to the center.

6. A package for a solid-state imaging device, the package comprising a recessed portion formed to mount a solid-state imaging element at a center,
the package including a package bottom having the recessed portion formed at the center and a package top joined onto the package bottom, wherein at least one of four corners of the package top has an outside shape placed outside an outside shape of a corner of the package bottom with respect to the center.

7. The package for a solid-state imaging device according to claim 4, wherein the top layer is formed of a plurality of ceramic layers.

8. The package for a solid-state imaging device according to claim 2, wherein at a point where the corner of the plate-like member of the top layer has an outside shape placed outside the outside shape of the corner of the plate-like member disposed under the plate-like member of the top layer, the corner of the plate-like member disposed under the plate-like member of the top layer is formed into a blur preventing shape including a round, a reversely rounded portion, a chamfer, a notch, and a recessed portion.

9. The package for a solid-state imaging device according to claim 6, wherein at a point where the corner of the package top has an outside shape placed outside the outside shape of the corner of the package bottom with respect to the center, a plate-like member disposed under a plate-like member of a top layer has a corner formed into a blur preventing shape including a round, a reversely rounded portion, a chamfer, a notch, and a recessed portion.

10. The package for a solid-state imaging device according to claim 8, further comprising one of side plating and underside plating, the side plating being formed on a portion having the blur preventing shape, the underside plating being formed to correspond to the portion having the blur preventing shape on a bottom of the package.

11. The package for a solid-state imaging device according to claim 9, further comprising one of side plating and underside plating, the side plating being formed on a portion having the blur preventing shape, the underside plating being formed to correspond to the portion having the blur preventing shape on a bottom of the package.

12. The package for a solid-state imaging device according to claim 4, wherein at least one of four corners of a plate-like member of a bottom layer has an outside shape placed, with respect to the center, outside an outside shape of a corner of a plate-like member other than a plate-like member of the top layer, out of plate-like members of the layers disposed on the plate-like member of the bottom layer.

13. The package for a solid-state imaging device according to claim 12, wherein the bottom layer is formed of a plurality of ceramic layers.

14. A method of manufacturing a package for an optical device, when dividing a laminated sheet including stacked ceramic sheets into pieces and forming the package for the optical device, the package including a recessed portion formed to mount a solid-state imaging element at a center,
the method comprising:
forming a first sheet on a ceramic sheet of a base, the first sheet including the stacked ceramic sheets having a first hole formed on a portion corresponding to the recessed portion of each package;
forming a second hole on at least one of corners of portions corresponding to four corners of each package of the first sheet, the second hole acting as a blur preventing shape when the sheet is divided into pieces;
stacking a second sheet on the first sheet, the second sheet having a third hole formed to correspond to the first hole;
forming a cut on a portion corresponding to an outside shape of each package on at least one of a top surface and an underside of a laminated sheet of the first sheet and the second sheet;
baking the laminated sheet including the first sheet and the second sheet with the formed cut; and
dividing the laminated sheet at the cut into packages after the baking.

15. A method of manufacturing a package for a solid-state imaging device, when dividing a laminated sheet including stacked ceramic sheets into pieces and forming the package for the solid-state imaging device, the package including a recessed portion formed to mount a solid-state imaging element at a center,
the method comprising:
forming a first sheet on a ceramic sheet of a base, the first sheet including the stacked ceramic sheets having a first hole formed on a portion corresponding to the recessed portion of each package;
forming a second hole on at least one of corners of portions corresponding to four corners of each package of the first sheet, the second hole acting as a blur preventing shape when the sheet is divided into pieces;
stacking a second sheet on the first sheet, the second sheet having a third hole formed to correspond to the first hole;
forming a cut on a portion corresponding to an outside shape of each package on at least one of a top surface and an underside of a laminated sheet of the first sheet and the second sheet;
baking the laminated sheet including the first sheet and the second sheet with the formed cut; and
dividing the laminated sheet at the cut into packages after the baking.

16. A solid-state imaging device comprising a solid-state imaging element on a recessed portion of the package for a solid-state imaging device according to claim 2.

17. A solid-state imaging device comprising a solid-state imaging element on a recessed portion of the package for a solid-state imaging device according to claim 4.

18. A solid-state imaging device comprising a solid-state imaging element on a recessed portion of the package for a solid-state imaging device according to claim 6.
